(19) United States
(12) Patent Application Publication
(10) Pub. No.: US 2017/0105528 A1
(43) Pub. Date: Apr. 20, 2017

(54) Neat Shelf

(71) Applicants: Tammy Mae Keller, Limestone, TN (US); Stacy Lynn Rounds, Johnson City, TN (US)

(72) Inventors: Tammy Mae Keller, Limestone, TN (US); Stacy Lynn Rounds, Johnson City, TN (US)

(21) Appl. No.: 14/887,503

(22) Filed: Oct. 20, 2015

(51) Int. Cl. A47B 97/00; A47B 96/02; A47B 21/06; F16M 13/02; H05K 7/02; H05K 7/18; A47B 81/00; A47B 96/06

(52) U.S. Cl. CPC A47B 97/00; A47B 81/00; A47B 96/028; A47B 96/066; F16M 13/02; H05K 7/02; H05K 7/18; A47B 21/06; A47B 2097/003; A47B 2021/066

(57) ABSTRACT

This invention relates to a device comprising of a floating shelf, a power strip that is secured inside the floating shelf, and a wall bracket to attach the floating shelf to wall. The device holds the peripherals mounted on it, hides the wires, cables, cords, and the like, and also powers the peripherals. With the device, only a cable connected to the power strip comes out. The power strip cable can be covered using a cable sheath.

### CROSS REFERENCE TO RELATED APPLICATIONS

Not applicable

### FEDERALLY SPONSORED RESEARCH AND DEVELOPMENT

Not applicable.

### MICROFICHE

Not applicable

### BACKGROUND OF THE INVENTION

(1) Field of the Invention

The present invention relates generally to shelving systems and the associated framework, brackets, shelves, and other components. More particularly, the present invention relates to a device that provides improvements in positioning and storing electrical wiring.

(2) Background of the Invention

Various TV stands with shelves that are mounted on the wall to secure the TV screen and hide wire, cables, cords or like have come up in past. The shelves of these stands also hold various peripheral devices, such as a DVD player, surround sound system, etc. None of these TV stands or similar devices provide for supplying power to the peripheral devices held upon shelves of the stands while performing the aforementioned tasks. For example, US Pat. App. 20060214072 discloses a flat panel display TV stand that includes a main frame that is fastened to a wall to stably accommodate a flat panel display TV (e.g. LCD or PDP) and a panel positioned in front of the main frame while hiding wires.

Another prior art, U.S. Pat. No. 4,549,777, discloses a mobile storage unit that has safety devices mounted to storage shelves. These may be quickly and conveniently repositioned on the unit frame while protecting the electrical wires and maintaining a neat appearance. This is accomplished by an elongated guide channel member joined to an upright unit frame. The channel member defines a vertical passage for storing and protecting the wires and includes one or more slots through which the wires pass from the safety device to the vertical passage.

Another prior art, U.S. Pat. No. 7,868,250, discloses an apparatus for supporting a variety of electronic devices during charging, as well as for organizing and managing the power cords of those devices.

Yet another prior art, US Pat App. 20070159035, provides a wall desk that includes first and second compartments separated by a partition with a passage sized to allow one or more electrical cables to pass between the compartments. A panel of the wall desk may flip down from a closed position covering the first compartment to an open position providing a work surface and affording access to the first compartment. The second compartment may be sized to house an electrical socket and to store electrical cables connected to electronic devices stored in the first compartment or used on the work surface.

All the prior arts tend to provide apparatus or device that holds electronic items or devices in one place while hiding their wires and cables.

Thus, there is a long-felt need to provide an apparatus or a device that powers the electronic devices it holds along with hiding and housing the wires, cables, cords, or the like. Therefore, in this way, this invention provides a device that provides power supply to the housed electronic devices while hiding the wires, cables, cords, or like.

### SUMMARY OF THE INVENTION

In the view of the foregoing disadvantages inherent in the known types of shelving systems for positioning and storing electrical wires now present in the prior art, the present invention provides an improved device that provides improvements in positioning and storing electrical wiring. As such, the general purpose of the present invention, which will be described subsequently in greater detail, is to provide a new and improved device that has all the advantages of the prior art and none of the disadvantages.

An objective of the invention is to provide a device for housing and hiding electrical wires, cables, cords, and the like of peripheral systems.

It is another objective of the present invention to provide a device that holds peripherals, such as a cable box, surround system, DVD player, game system, etc.

It is another objective of the present invention to provide a device that powers all of the peripherals it holds.

It is another objective of the present invention to provide a device that is stylish and adds to decor.

It is another objective of the present invention to provide a device that lends a neat appearance to a room.

It is another objective of the present invention to provide a device that mounts on the wall.

It is another objective of the present invention to provide a device that is more versatile, streamlined, and functional than a TV stand that hides cords or a stand-alone floating shelf.

In this respect, before explaining at least one embodiment of the invention in detail, it is to be understood that the invention is not limited in its application to the details of construction and to the arrangements of the components set forth in the following description or illustrated in the drawings. The invention is capable of other embodiments, and of being practiced and carried out in various ways. Also, it is to be understood that the phraseology and terminology employed herein are for the purpose of description, and should not be regarded as limiting.

These, together with other objectives of the invention and the various features of novelty that characterize the invention, are pointed out with particularity in the disclosure. For a better understanding of the invention, its operating advantages, and the specific objectives attained by its uses, reference should be had to the accompanying drawings and descriptive matter, in which there are illustrated preferred embodiments of the invention.

### BRIEF DESCRIPTION OF THE DRAWINGS

The invention will be better understood, and objectives other than those set forth above will become apparent, when consideration is given to the following detailed description thereof. Such description makes reference to the annexed drawings wherein:

FIG. 1 shows the preferred embodiment of present invention.

### DETAILED DESCRIPTION OF THE INVENTION

In the following detailed description, reference is made to the accompanying drawing, which forms a part hereof, and in which is shown, by way of illustration, specific embodiments in which the invention may be practiced. These embodiments are described in sufficient detail to enable those skilled in the art to practice the invention, and it is to be understood that the embodiments may be combined, or that other embodiments may be utilized, and that structural, logical, and electrical changes may be made without departing from the spirit and scope of the present invention. The following detailed description is, therefore, not to be taken in a limiting sense, and the scope of the present invention is defined by the appended claims and their equivalents.

The present invention provides a device that is much more versatile, streamlined, and functional than television stands that hide cords or a stand-alone floating shelf The device will hide electrical wires or cables for a neat appearance (under TV's, for small appliances in the kitchen for T.V.'s/stereos/etc. in the bedroom etc.), will hold the electronic peripherals in place, and will also provide means to lend power to peripherals. Hereinafter, a preferred embodiment of the present invention will be described with reference to the accompanying drawing. In the following description and drawing, the same reference numerals are used to designate the same or similar components, and so repetition of the description on the same or similar components will be omitted.

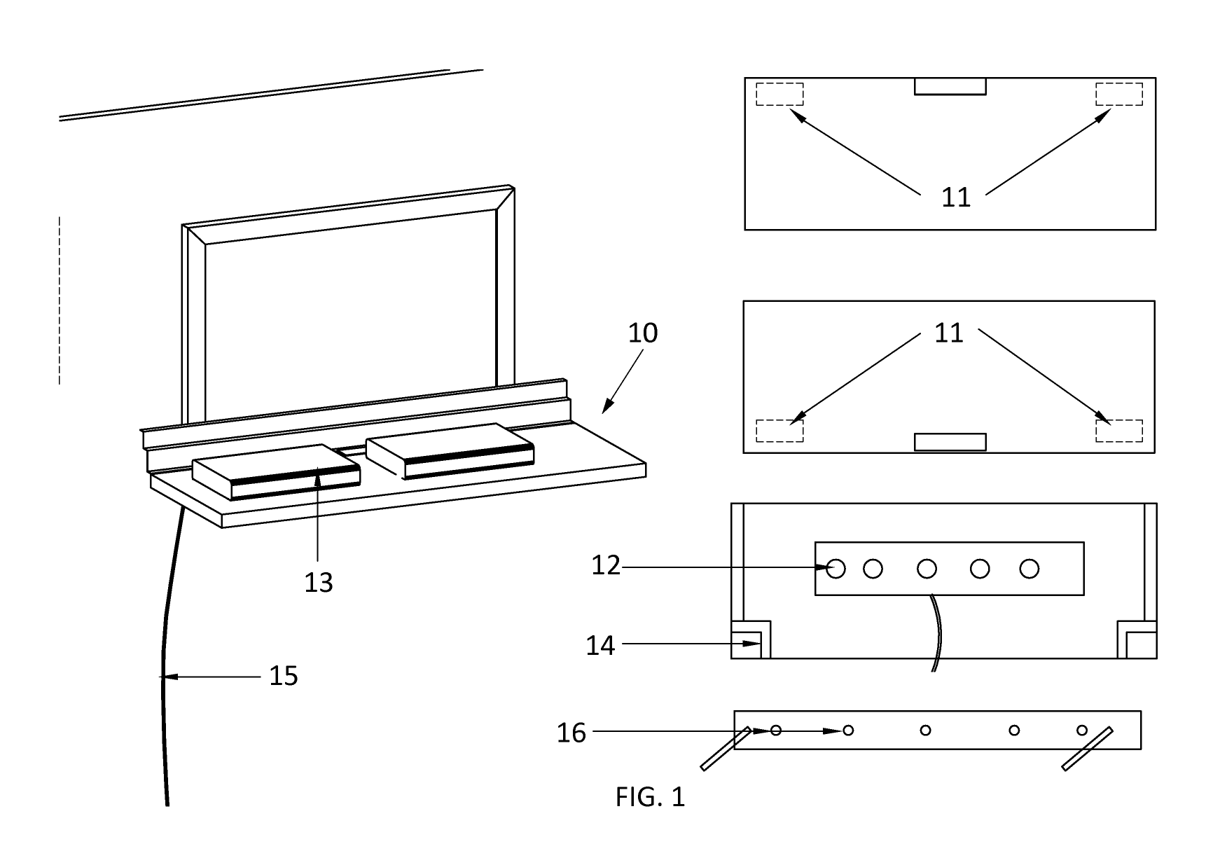

FIG. 1 shows a shelf 10 made from wood. The shelf is hollow and is laminated so that it lends style and enhances appearance. Perforated cut-outs for cords 11 of the electric items have been provided on the top and bottom of the shelf for accommodating cable, wires, cords, and the like inside of the hollow shelf. All of the electronic peripherals 13 are placed on the shelf, as shown on FIGURE. A single power strip 12 is mounted to the back wall of the shelf. The power strip will serve as a means for power to the electronic peripherals. The FIGURE also shows the brackets 14 hiding into the provided insertion holes, which also contribute to overall appearance of device. The power strip is connected to a single power cord that comes out of the shelf. A cable sheath 15 covers the single power cord coming out of the shelf. The insertion holes 16 are provided for screws to be drilled into studs on the wall. The insertion holes are arranged in longitudinal direction with a predetermined spacing between them.

The peripherals can be any electronic appliance with cable, wires, cord, and the like, such as a satellite box, DVD player, surround sound system, speakers, gaming systems, DVD/Blu ray players, etc. The shelf is designed to hold the electronic peripherals, and hide all of the wires associated with respected peripherals inside it, leaving only the single cable associated with power strip to be covered with a cable sheath. The shelf can be styled to match any décor and gives net appearance. The shelf thereby increases the aesthetics of room or place it is used in. The shelf's size can be but is not limited to 48 inches in length, 12 inches in width, and 3.5 inches in height.

Advantageously, the present invention is much more versatile, streamlined, functional, and different from the existing knowledge. The present invention can hide wires, cables, cords and other (like) such means used to supply power to the peripheral. The device also holds and powers the peripherals. But the device is not limited to the preferred embodiment of the invention but can be used in kids' rooms for their gaming systems. It can also be set up as a charging station for the kids' electronics. Furthermore, the shelf can be used to hold lights, electronic beauty products, etc. in a bathroom. It can also be used in a garage or a work area to set up charging station for power tools such as power drill.

It is to be understood that the above description is intended to be illustrative, and not restrictive. For example, the above-discussed embodiments may be used in combination with each other. Many other embodiments will be apparent to those of skill in the art upon reviewing the above description.

The benefits and advantages that may be provided by the present invention have been described above with regard to specific embodiments. These benefits and advantages, and any elements or limitations that may cause them to occur or to become more pronounced, are not to be construed as critical, required, or essential features of any or all of the embodiments.

While the present invention has been described with reference to particular embodiments, it should be understood that the embodiments are illustrative, and that the scope of the invention is not limited to these embodiments. Many variations, modifications, additions, and improvements to the embodiments described above are possible. It is contemplated that these variations, modifications, additions and improvements fall within the scope of the invention.

I/we claim:

1. A device for housing and hiding wires, cables, cords and like, the device comprising:
a floating shelf;
a power strip; and
a wall bracket.

2. The device according to claim 1, wherein said floating shelf is made up of hollow wood that is laminated.

3. The device according to claim 1, wherein said floating shelf is so designed that it adds to neat appearance and décor.

4. The device according to claim 1, wherein said floating shelf holds peripherals such as cable box, surround sound, game system, DVD system etc.

5. The device according to claim 1, wherein said floating shelf is provided with perforated cut outs for cords.

6. The device according to claim 1, wherein said power strip is secured inside said floating shelf.

7. The device according to claim 1, wherein said power strip powers electronic items held by said floating shelf.

8. The device according to claim 1, wherein said cord connected to said power strip is covered by a cable sheath.

9. The device according to claim 1, wherein said wall bracket attaches said floating shelf to the wall.

10. The device according to claim 1, wherein said wall bracket can be made of metal or wood.
